(19) United States
(12) Patent Application Publication
(10) Pub. No.: US 2026/0068618 A1
(43) Pub. Date: Mar. 5, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Chin-Lung CHUNG, Hsinchu (TW); Tsu-Chun KUO, Hsinchu (TW); Han-Tang HUNG, Hsinchu (TW)

(73) Assignee: Taiwan Semiconductor Manufacturing Company, Ltd., Hsinchu (TW)

(21) Appl. No.: 18/817,414

(22) Filed: Aug. 28, 2024

(51) Int. Cl. H01L 21/768; H01L 23/535

(52) U.S. Cl. CPC H01L 21/76895

(57) ABSTRACT

A semiconductor structure includes a substrate and a back end of line (BEOL) layer disposed on the substrate. The BEOL layer includes a first dielectric layer, a via conductive portion, a second dielectric layer and a liner. The first dielectric layer has a surface and a via-hole extends from the surface. The via conductive portion is disposed within the via-hole and has a recess recessed relative to the surface. The second dielectric layer is disposed on the first dielectric layer, wherein the second dielectric layer has a metal-trench exposing the recess. The liner is disposed on a sidewall of the metal-trench and separated from the via conductive portion.

### BACKGROUND

As critical dimension shrinks, the conventional dual damascene (DD) structure makes metal gap-fill become challenging due to high aspect ratio (AR) and small opening. Thus, via and trench structure fabricated by single damascene (SD) separately could overcome this problem. However, the single-damascene via recess (metal dishing) was found after CMP planarization and following etching stop layer was embedded which cause high contact resistance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a local cross-sectional view of a semiconductor structure according to an embodiment of the present disclosure;

FIG. 2 illustrates a schematic diagram of a local cross-sectional view of a semiconductor structure according to another embodiment of the present disclosure;

FIG. 3 illustrates a schematic diagram of a local cross-sectional view of a semiconductor structure according to another embodiment of the present disclosure;

FIGS. 4A to 4K illustrate schematic diagrams of manufacturing processes of the semiconductor structure in FIG. 1;

FIGS. 5A to 5J illustrate schematic diagrams of manufacturing processes of the semiconductor structure in FIG. 2; and

FIGS. 6A to 6I illustrate schematic diagrams of manufacturing processes of the semiconductor structure in FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

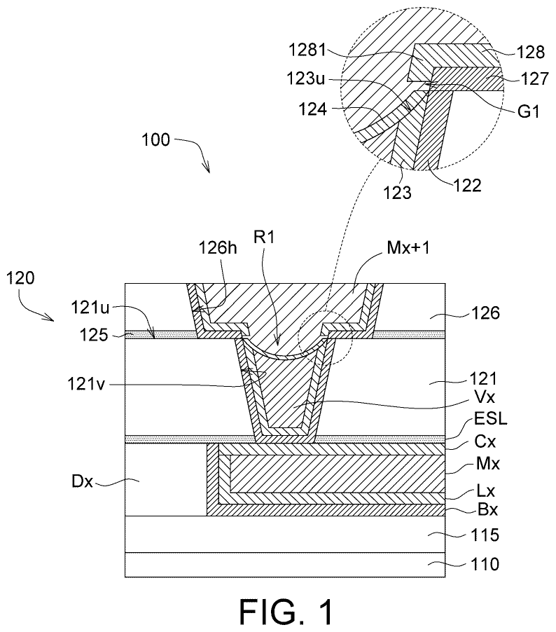

Referring to FIG. 1, FIG. 1 illustrates a schematic diagram of a local cross-sectional view of a semiconductor structure 100 according to an embodiment of the present disclosure.

As illustrated in FIG. 1, the semiconductor structure 100 includes a substrate 110, a mid-end-of-line (MEOL) layer 115 and a back-end-of-line (BEOL) layer 120. The substrate 110 is, for example, a portion of a silicon wafer. The MEOL layer 115 is formed on the substrate 110. The BEOL layer 120 is formed on the substrate 110 through the MEOL layer 115.

As illustrated in FIG. 1, the BEOL layer 120 includes a first dielectric layer 121, a first barrier layer 122, a first liner 123, a cap 124, a first etching stop layer 125, a second dielectric layer 126, a second barrier layer 127, a second liner 128, an etching stop layer ESL, a dielectric layer Dₓ, an via conductive portion Vₓ, a metal conductive portion Mₓ, a barrier layer Bₓ, a liner Lₓ, a cap Cₓ, and a metal conductive portion Mₓ₊₁. The subscript “x”may be 1.

In another embodiment, the BEOL layer 120 may further comprises at least one via conductive portion Vₓ and at least one metal conductive portion Mₓ disposed above the metal conductive portion M₁, wherein the subscript “x” may range between 2 and N, and N is a positive integer greater than 2.

As illustrated in FIG. 1, t he dielectric layer Dₓ is formed in the MEOL layer 115. The dielectric layer Dₓ is patterned. Furthermore, the dielectric layer Dₓ has at least one metal-trench within which the barrier layer Bₓ, the liner Lₓ, the cap Cₓ and the metal conductive portion Mₓ are formed. The etching stop layer ESL is formed over the dielectric layer Dₓ and the cap Cₓ, and the via conductive portion Vₓ is connected to the metal conductive portion Mₓ through the first dielectric layer 121.

As illustrated in FIG. 1, the first dielectric layer 121 has a surface 121u and a via-hole 121v extending from the surface 121u. The via-hole 121v extends to the aforementioned metal conductive portion Mₓ through the etching stop layer ESL. The via conductive portion Vₓ is disposed within the via-hole 121v and has a recess R1 recessed relative to the surface 121u. The second dielectric layer 126 is formed over the first dielectric layer 121, wherein the second dielectric layer 126 has a metal-trench 126h exposing the recess R1. The second liner 128 is formed on a side wall of the metal-trench 126h and separated from the via conductive portion Vₓ. In the present embodiment, there is no residue ESL (etching stop layer) material in the recess R1, and thus the resistance of the conductive portion may be effectively reduced.

As illustrated in FIG. 1, the first barrier layer 122 is formed on a sidewall of the via-hole 121v, an upper surface of the cap Cₓ and a sidewall of the etching stop layer ESL. The first liner 123 is formed over the first barrier layer 122. The first liner 123 has an upper surface 123u which is formed by a planarization process, for example, a CMP (Chemical-Mechanical Planarization). The upper surface 123u is covered by the cap 124. Similarly, the via conductive portion Vₓ has an upper surface S1 which is formed by the planarization process, for example, a CMP, and the upper surface S1 is covered by the cap 124. The upper surface S1 of the via conductive portion Vₓ and the upper surface 123u of the first liner 123 may formed in the same planarization process.

The liner may be formed by ALD, CVD and wet coating process. The liner may be formed of a material including a metal (for example, Co) and/or an alloy (for example, CoW, CoZrTa). The barrier layer may be formed by ALD, CVD and wet coating process. The barrier layer may be formed of a material including a metal nitride (for example, TaN), a metal oxide (for example, TiOx) and/or alloy (for example, CoNb).

As illustrated in FIG. 1, the metal conductive portion Mₓ₊₁ is formed within the metal-trench 126h and extends toward the via conductive portion Vₓ. In the present embodiment, the metal conductive portion Mₓ₊₁ and the via conductive portion Vx may be formed by, for example, single damascene (SD) process. The SD process may be suitable for a situation where the aspect ratio (AR) of the conductive portion ranges between 2 and 3, for example.

As illustrated in FIG. 1, i n the present embodiment, the metal conductive portion Mₓ₊₁ is not contact with the via conductive portion Vₓ. Furthermore, the cap 124 covers the via conductive portion Vₓ. The cap 124 is formed between the metal conductive portion Mₓ₊₁ and the via conductive portion Vₓ, and separates the metal conductive portion Mₓ₊₁ from the via conductive portion Vₓ. The cap 124 is in contact with the metal conductive portion Vₓ. The cap 124 may be formed of a material the same as or similar to that of the first liner 123.

The metal conductive portion and the via conductive portion may be formed by using, for example, CVD (Chemical Vapor Deposition), ALD (Atomic Layer Deposition), PVD (Physical Vapor Deposition), ECP (Electro-Chemical-Plating), electroless plating, etc. The metal conductive portion and the via conductive portion may be formed of a transition metal (for example, Cu, Co, Mo, W and Ru), an alloy (for example, CuMn, CuAl, CuMg, CoZr, etc.) and 2D materials.

As illustrated in FIG. 1, the first etching stop layer 125 is formed outside the via-hole 121v, and there is no material of the first etching stop layer 125 remain in the recess R1 and the via-hole 121v. The etching stop layer may be formed by ALD, CVD and wet coating process. The etching stop layer may be formed of a material including an organic (for example, SiOC) and/or inorganic (for example, AlxNy, AlOx) material.

As illustrated in FIG. 1, the second dielectric layer 126 is formed over the first etching stop layer 125. The second barrier layer 127 is formed on a sidewall of the metal-trench 126h, an upper surface of the first dielectric layer 121 and a sidewall of the first etching stop layer 125.

As illustrated in FIG. 1, the second liner 128 is formed over the second barrier layer 127. The liner 128 is spaced from the first liner 123 (or the via conductive portion Vₓ) by a gap G1. The metal conductive portion Mₓ₊₁ fills the gap G1. The second liner 128 includes a protrusion 1281 protruding relative to a lateral surface of the second barrier layer 127 and separated from the cap 124 by a portion of the metal conductive portion M_{x+1.}

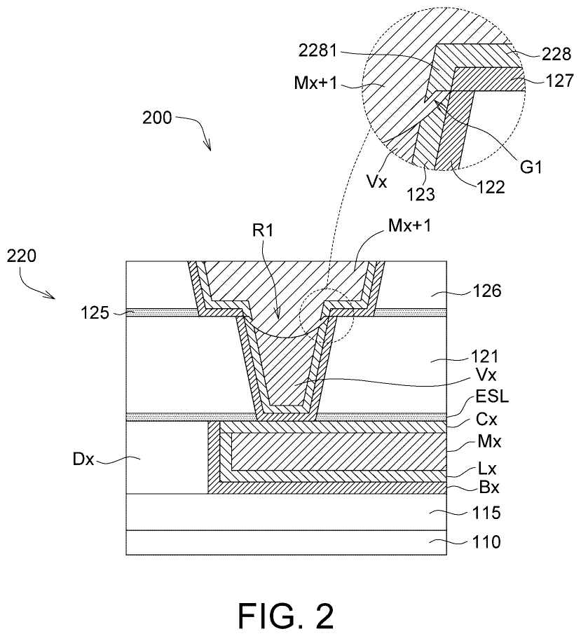

Referring to FIG. 2, FIG. 2 illustrates a schematic diagram of a local cross-sectional view of a semiconductor structure 200 according to another embodiment of the present disclosure. The semiconductor structure 200 includes the substrate 110, the MEOL layer 115 and a BEOL layer 220. The substrate 110 is, for example, a portion of a silicon wafer. The MEOL layer 115 is formed on the substrate 110. The BEOL layer 220 is formed on the substrate 110 through the MEOL layer 115.

As illustrated in FIG. 2, the BEOL layer 220 includes the first dielectric layer 121, the first barrier layer 122, the first liner 123, the first etching stop layer 125, the second dielectric layer 126, the second barrier layer 127, a second liner 228, the etching stop layer ESL, the dielectric layer Dₓ, at least one via conductive portion Vₓ, the metal conductive portion Mₓ, the barrier layer Bₓ, the liner Lₓ, the cap Cₓ, the metal conductive portion Mₓ₊₁.

The semiconductor structure 200 includes the features the same as or similar to that of the semiconductor structure 100, and at least one difference is that the BEOL layer 220 of the semiconductor structure 200 and the BEOL layer 120 of the semiconductor structure 100 are different in structure. Furthermore, the BEOL layer 220 may omit the cap 124. Furthermore, the metal conductive portion Mₓ₊₁ is contact with the via conductive portion Vₓ and the first liner 123.

As illustrated in FIG. 2, the second liner 228 includes a protrusion 2281 protruding relative to a lateral surface of the second barrier layer 127. The second liner 228 is separated from the first liner 123 by a gap G1, and a portion of the metal conductive portion Mₓ₊₁ may fill the gap G1.

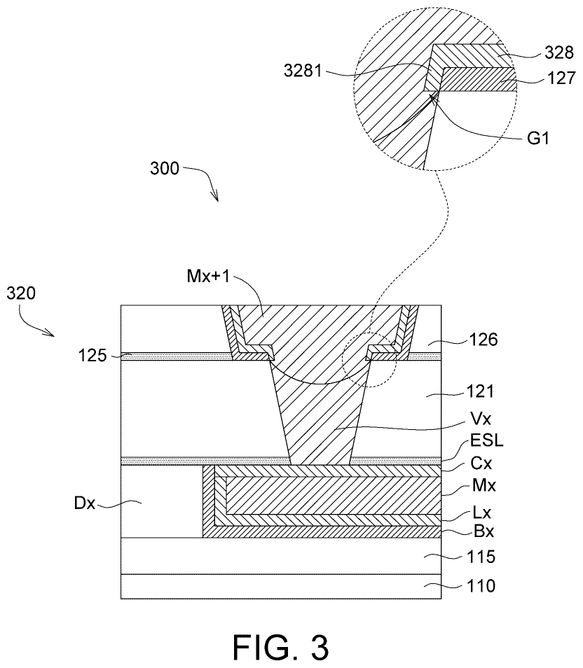

Referring to FIG. 3, FIG. 3 illustrates a schematic diagram of a local cross-sectional view of a semiconductor structure 300 according to another embodiment of the present disclosure. The semiconductor structure 300 includes the substrate 110, the MEOL layer 115 and a BEOL layer 320. The substrate 110 is, for example, a portion of a silicon wafer. The MEOL layer 115 is formed on the substrate 110. The BEOL layer 320 is formed on the substrate 110 through the MEOL layer 115.

As illustrated in FIG. 3, the BEOL layer 320 includes the first dielectric layer 121, the first barrier layer 122, the first liner 123, the first etching stop layer 125, the second dielectric layer 126, the second barrier layer 127, a second liner 328, the etching stop layer ESL, the dielectric layer Dₓ, at least one via conductive portion Vₓ, the metal conductive portion Mₓ, the barrier layer Bₓ, the liner Lₓ, the cap Cₓ and the metal conductive portion Mₓ₊₁.

As illustrated in FIG. 3, t he semiconductor structure 300 includes the features the same as or similar to that of the semiconductor structure 200, and at least one difference is that the BEOL layer 320 of the semiconductor structure 300 and the BEOL layer 220 of the semiconductor structure 200 are different in structure. Furthermore, the BEOL layer 320 may omit the cap 124, the first barrier layer 122 and the first liner 123. The metal conductive portion Mₓ₊₁ is contact with the via conductive portion V_{x.}

As illustrated in FIG. 3, the second liner 328 is formed over the second barrier layer 127. The second liner 328 is spaced from the via conductive portion Vₓ by a gap G1. The metal conductive portion Mₓ₊₁ fills the gap G1. The second liner 328 includes a protrusion 3281 protruding relative to a lateral surface of the second barrier layer 127 and separated from the via conductive portion Vₓ by a portion of the metal conductive portion M_{x+1.}

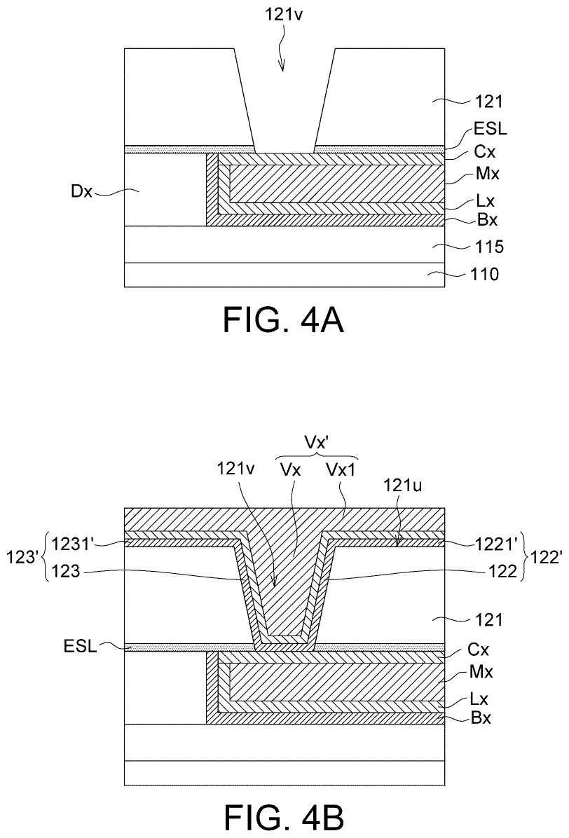

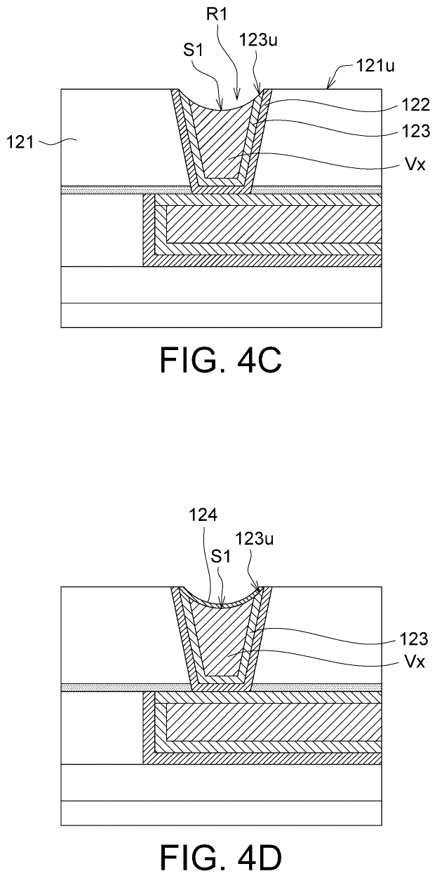

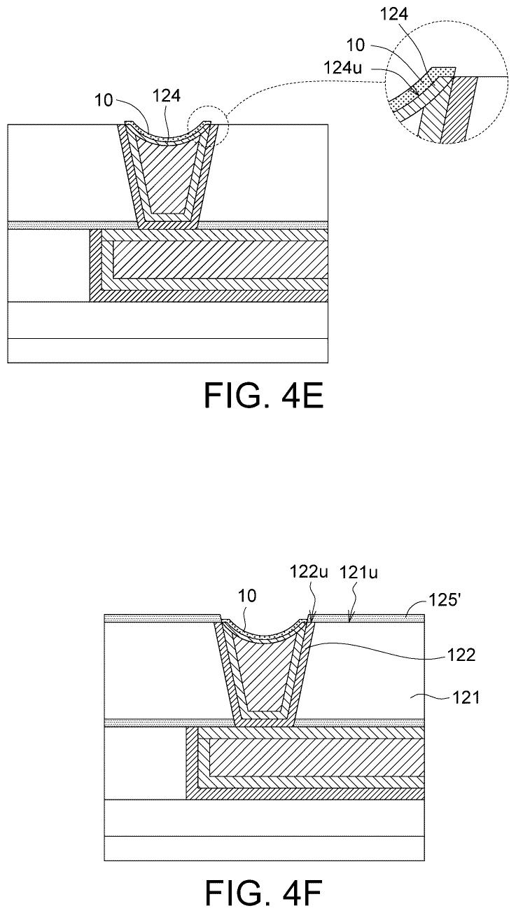

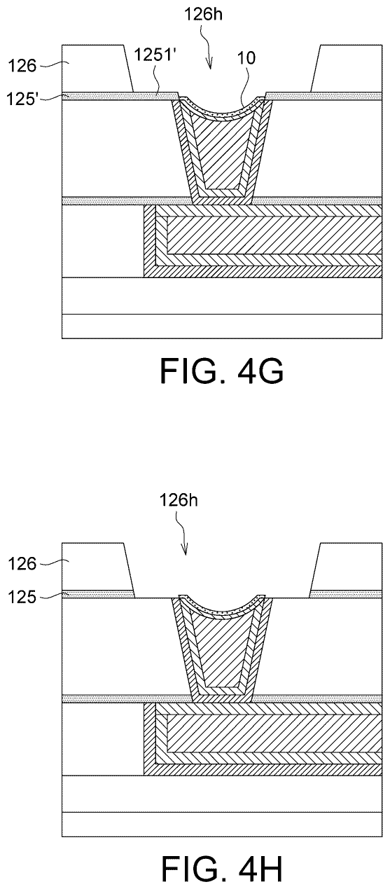

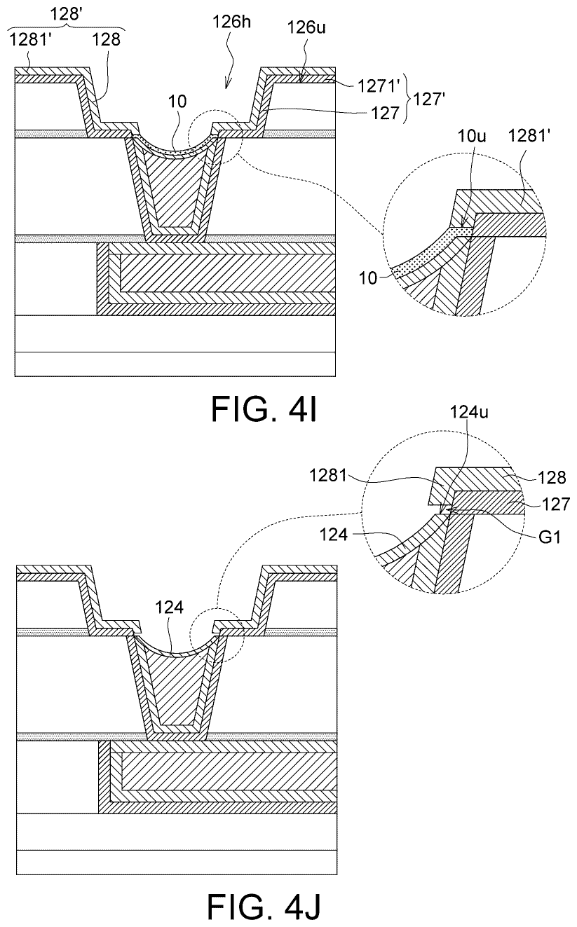

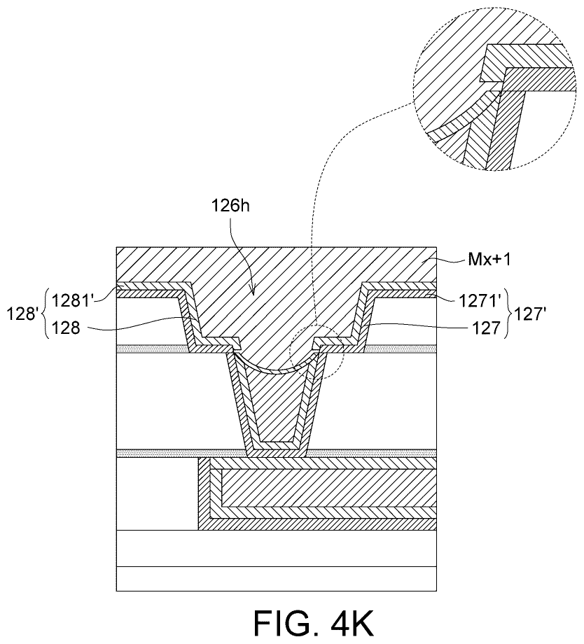

FIGS. 4A to 4K illustrate schematic diagrams of manufacturing processes of the semiconductor structure 100 in FIG. 1.

As illustrated in FIG. 4A, the MEOL layer 115 is formed on the substrate 110. The dielectric layer Dₓ having at least one hole within which the barrier layer Bₓ, the liner Lₓ, the metal conductive portion Mₓ and the cap Cₓ are formed. The etching stop layer ESL is formed on the dielectric layer Dₓ, and the cap Cₓ. The first dielectric layer 121 is formed on the etching stop layer ESL. The via-hole 121v is formed in the first dielectric layer 121 by using, for example, lithography, etc., and the via-hole 121v may stop at a portion of the etching stop layer ESL exposed from the via-hole 121v. Then, the portion of the etching stop layer ESL which is exposed from the via-hole 121v is removed by using, for example, wet etching.

As illustrated in FIG. 4B, a first barrier layer material 122′ including the first barrier layer 122 and a barrier layer 1221′ is formed by using, for example, deposition, etc. The first barrier layer 122 is formed on sidewalls of the via-hole 121v, and the barrier layer 1221′ is formed on an upper surface 121u of the first dielectric layer 121. In addition, the first barrier layer material 122′ may be formed at a temperature ranging between a room temperature to 400 degrees Celsius. Then, a first liner material 123′ including the first liner 123 and a liner 1231′ is formed over the first barrier layer material 122′ by using, for example, deposition, etc. The first liner 123 is formed on the first barrier layer 122, and the liner 1231′ is formed on the barrier layer 1221′. In addition, the first liner material 123′ may be formed at a temperature ranging between a room temperature to 400 degrees Celsius. Then, the via conductive portion material Vₓ′ including the via conductive portion Vₓ and a conductive portion Vₓ₁ by using, for example, deposition, etc. The via conductive portion Vₓ is formed on the first liner 123, and the conductive portion Vₓ₁ is formed on the liner 1231′. In addition, the via conductive portion material Vₓ′ may be formed at a temperature ranging between a room temperature to 400 degrees Celsius.

As illustrated in FIG. 4C, the first barrier layer 122, the first liner 123, the via conductive portion Vₓ and the first dielectric layer 121 may be planarized by using, for example, CMP. After planarized, the first liner 123 forms the upper surface 123u, the via conductive portion Vₓ forms the upper surface S1, and the first dielectric layer 121 forms the upper surface 121u. The upper surface S1 and the upper surface 123u may be recessed relative to the upper surface 121u to form the recess R1. The upper surface S1 and the upper surface 123 may form a continuous curved-surface or a continuous cambered-surface. In another embodiment, the first barrier layer 122 may form an upper surface recessed relative to the upper surface 121u, and the upper surface S1 of the via conductive portion Vₓ, the upper surface 123u of the first liner 123 and the upper surface of the first barrier layer 122 may form a continuous curved-surface or a continuous cambered-surface.

As illustrated in FIG. 4D, the cap 124 over the upper surface 123u of the first liner 123 and the upper surface S1 of the via conductive portion Vₓ is formed by using, for example, ALD, CVD and wet coating process.

As illustrated in FIG. 4E, a blocking layer 10 over the cap 124 is formed by using, for example, a dry process (for example, CVD, ALD, etc.) or a wet process (for example, spin coating, immersion, etc.). The material for the blocking layer 10 may be small molecules (for example, N-containing organic compound) or macromolecules (for example, polymer with functional group) . The blocking layer material may be adsorbed on the specific material (for example, the cap 124) to form the blocking layer 10. In the present embodiment, the blocking layer 10 overs an upper surface 124u and the cap 124. The blocking layer 10 may have a thickness ranging can be 1 angstrom (Å) to 1 micrometer (μm). In addition, the blocking layer 10 may be formed at a temperature ranging between a room temperature to 400 degrees Celsius.

As illustrated in FIG. 4F, the first etching stop layer material 125′ over the upper surface 121u of the first dielectric layer 121 and an upper surface 122u of the first barrier layer 122 is formed by using, for example, deposition. Due to blocking of the blocking layer 10, the first etching stop layer material 125′ is not formed over the blocking layer 10. In addition, the first etching stop layer material 125′ may be formed at a temperature ranging between a room temperature to 400 degrees Celsius. In addition, the first etching stop layer material 125′ may be formed of a material including an organic (for example, SiOC) and/or inorganic (for example, AlxNy, AlOx) material.

As illustrated in FIG. 4G, the second dielectric layer 126 having at least one metal-trench 126h is formed over the first etching stop layer material 125′ by, for example, lithography, etc. The metal-trench 126h stops at the blocking layer 10 and a portion 1251′ of the first etching stop layer material 125′ in, for example, etching process.

As illustrated in FIG. 4H, the portion 1251′ of the first etching stop layer material 125′ may be removed by using, for example, wet etching.

As illustrated in FIG. 4I, a second barrier layer material 127′ including the second barrier layer 127 and a barrier layer 1271′ is formed by using, for example, ALD, CVD, wet coating process, etc. The second barrier layer 127 is formed on sidewalls of the metal-trench 126h, and the barrier layer 1271′ is formed on an upper surface 126u of the second dielectric layer 126. Then, a second liner material 128′ including the second liner 128 and a liner 1281′ is formed by, for example, ALD, CVD and wet coating process. The second liner 128 is formed over the second barrier layer 127, and the liner 1281′ is formed over the barrier layer 1271′ and a portion of an upper surface 10u of the blocking layer 10.

As illustrated in FIG. 4J, the blocking layer 10 is removed by using, for example, a thermal degradation, a plasma bombard, an electrical-assisted desorption, etc. The liner 128 includes the protrusion 1281 protruding relative to a lateral surface of the second barrier layer 127. The protrusion 1281 is separated from the upper surface 124u of the cap 124 by the gap G1.

As illustrated in FIG. 4K, the metal conductive portion Mₓ₊₁ filling the metal-trench 126h and the gap G1 and over the second barrier layer material 127′ is formed by using, for example, CVD, ALD, PVD, ECP, electroless plating, etc.

Then, the metal conductive portion Mₓ₊₁, the barrier layer 1271′ and the liner 1281′ may be planarized by, for example, CMP, to from the semiconductor structure 100 in FIG. 1.

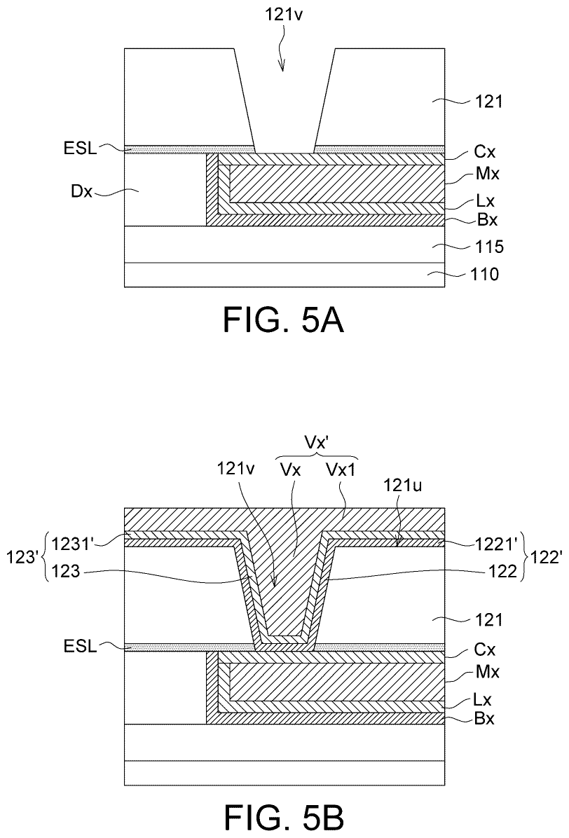

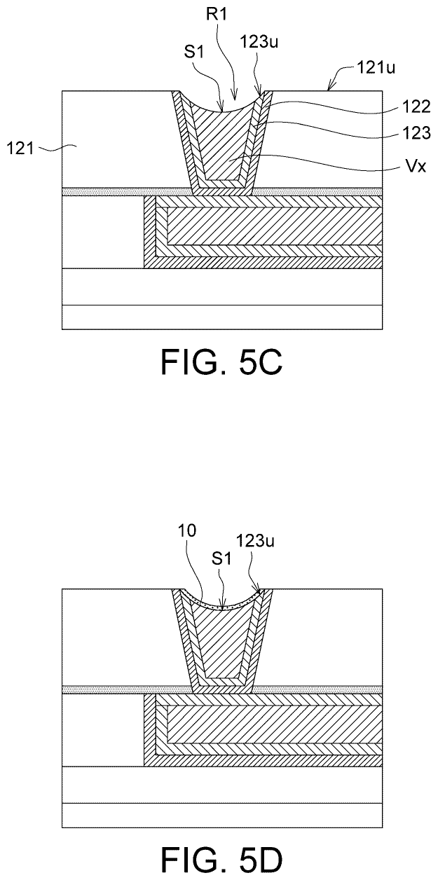

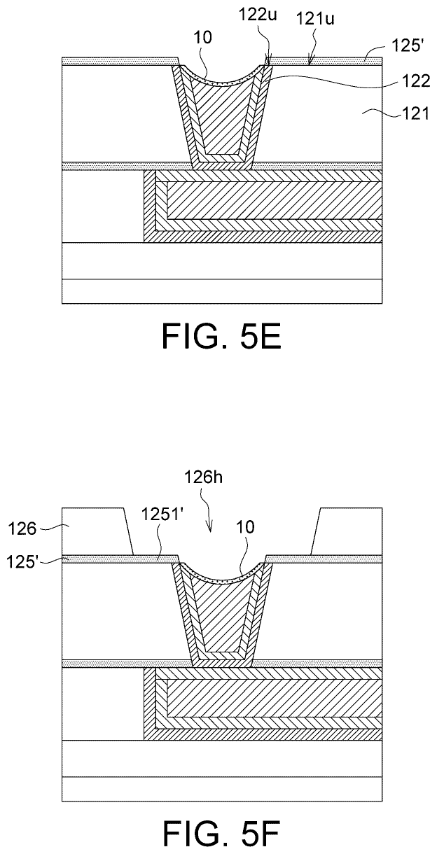

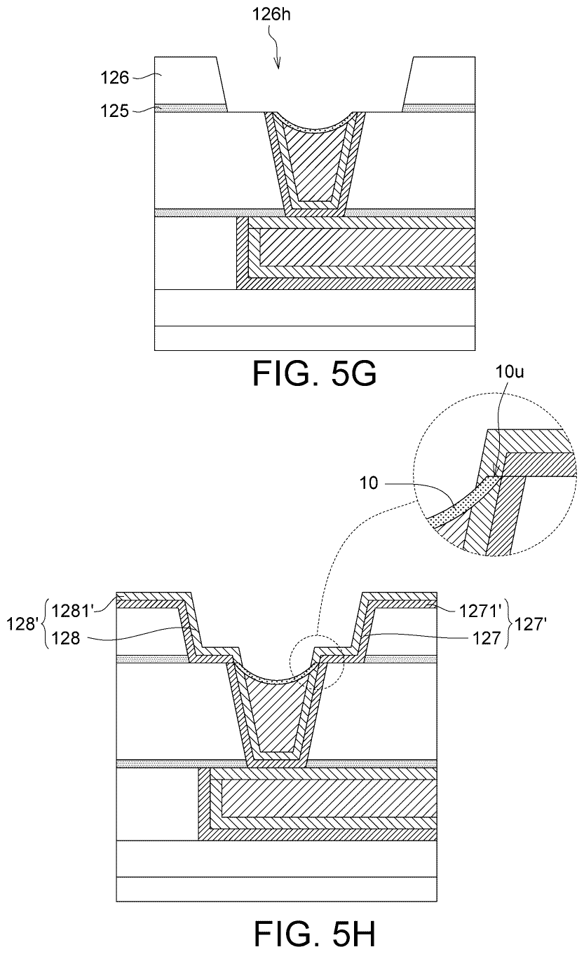

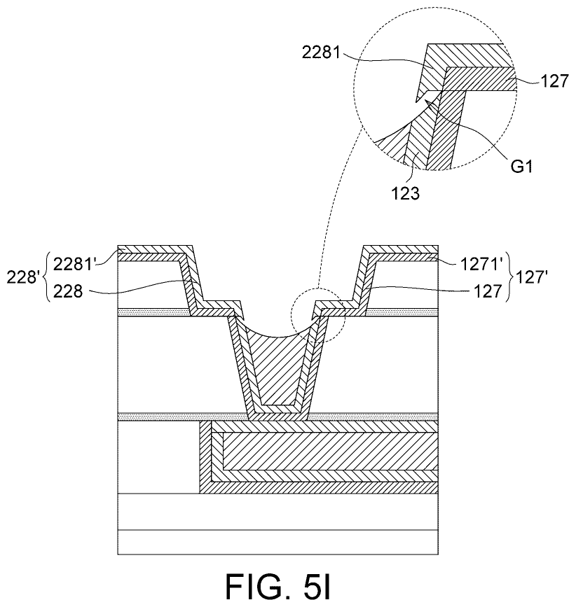

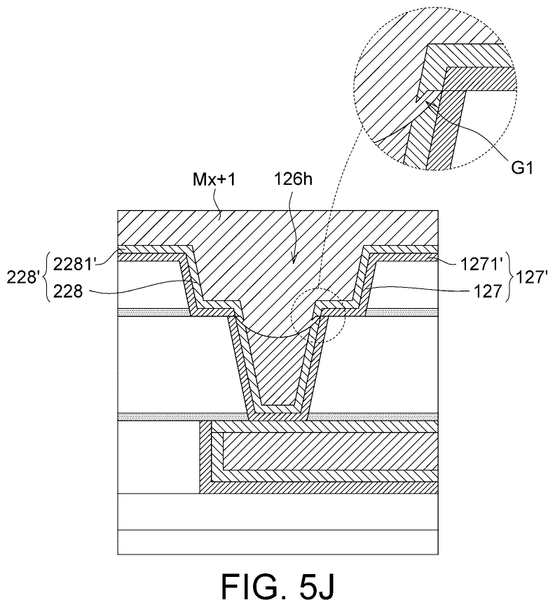

FIGS. 5A to 5J illustrate schematic diagrams of manufacturing processes of the semiconductor structure 200 in FIG. 2.

As illustrated in FIG. 5A, the MEOL layer 115 is formed on the substrate 110. The dielectric layer Dₓ having at least one hole within which the barrier layer Bₓ, the liner Lₓ, the metal conductive portion Mₓ and the cap Cₓ are formed. The etching stop layer ESL is formed on the dielectric layer Dₓ, and the cap Cₓ. The first dielectric layer 121 is formed on the etching stop layer ESL. The via-hole 121v is formed in the first dielectric layer 121 by using, for example, lithography, etc., and the via-hole 121v may stop at a portion of the etching stop layer ESL exposed from the via-hole 121v. Then, the portion of the etching stop layer ESL which is exposed from the via-hole 121v is removed by using, for example, wet etching.

As illustrated in FIG. 5B, the first barrier layer material 122′ including the first barrier layer 122 and the barrier layer 1221′ is formed by using, for example, deposition, etc. The first barrier layer 122 is formed on sidewalls of the via-hole 121v, and the barrier layer 1221′ is formed on the upper surface 121u of the first dielectric layer 121. Then, a first liner material 123′ including the first liner 123 and the liner 1231′ is formed over the first barrier layer material 122′ by using, for example, deposition, etc. The first liner 123 is formed on the first barrier layer 122, and the liner 1231′ is formed on the barrier layer 1221′. Then, the via conductive portion material Vₓ′ including the via conductive portion Vₓ and the conductive portion Vₓ₁ by using, for example, deposition, etc. The via conductive portion Vₓ is formed on the first liner 123, and the conductive portion Vₓ₁ is formed on the liner 1231′.

As illustrated in FIG. 5C, the first barrier layer 122, the first liner 123, the via conductive portion Vₓ and the first dielectric layer 121 may be planarized by using, for example, CMP. After planarized, the first liner 123 forms the upper surface 123u, the via conductive portion Vₓ forms the upper surface S1, and the first dielectric layer 121 forms the upper surface 121u. The upper surface S1 and the upper surface 123u may be recessed relative to the upper surface 121u to form the recess R1. The upper surface S1 and the upper surface 123 may form a continuous curved-surface or a continuous cambered-surface. In another embodiment, the first barrier layer 122 may form an upper surface recessed relative to the upper surface 121u, and the upper surface S1 of the via conductive portion Vₓ, the upper surface 123u of the first liner 123 and the upper surface of the first barrier layer 122 may form a continuous curved-surface or a continuous cambered-surface.

As illustrated in FIG. 5D, the blocking layer 10 over the upper surface S1 of the via conductive portion Vₓ and the upper surface 123u of the first liner 123 is formed by using, for example, a dry process (for example, CVD, ALD, etc.) or a wet process (for example, spin coating, immersion, etc.). The material for the blocking layer 10 may be small molecules (for example, N-containing organic compound) or macromolecules (for example, polymer with functional group). The blocking layer material may be adsorbed on the specific material (for example, the first liner 123 and the via conductive portion Vₓ) to form the blocking layer 10. The blocking layer 10 may have a thickness ranging can be 1 Å to 1 μm. In addition, the blocking layer 10 may be formed at a temperature ranging between a room temperature to 400 degrees Celsius.

As illustrated in FIG. 5E, the first etching stop layer material 125′ over the upper surface 121u of the first dielectric layer 121 and an upper surface 122u of the first barrier layer 122 is formed by using, for example, deposition. Due to blocking of the blocking layer 10, the first etching stop layer material 125′ is not formed over the blocking layer 10. In addition, the first etching stop layer material 125′ may be formed at a temperature ranging between a room temperature to 400 degrees Celsius. In addition, the first etching stop layer material 125′ may be formed of a material including an organic (for example, SiOC) and/or inorganic (for example, AlxNy, AlOx) material.

As illustrated in FIG. 5F, the second dielectric layer 126 having at least one metal-trench 126h is formed over the first etching stop layer material 125′ by, for example, lithography, etc. The metal-trench 126h stops at the blocking layer 10 and the portion 1251′ of the first etching stop layer material 125′ in, for example, etching process.

As illustrated in FIG. 5G, the portion 1251′ of the first etching stop layer material 125′ may be removed by using, for example, wet etching.

As illustrated in FIG. 5H, a second barrier layer material 127′ including the second barrier layer 127 and the barrier layer 1271′ is formed by using, for example, ALD, CVD, wet coating process, etc. The second barrier layer 127 is formed on sidewalls of the metal-trench 126h, and the barrier layer 1271′ is formed on the upper surface 126u of the second dielectric layer 126. Then, a second liner material 228′ including the second liner 228 and a liner 1281′ is formed by, for example, ALD, CVD and wet coating process. The second liner 228 is formed over the second barrier layer 127, and the liner 1281′ is formed over the barrier layer 1271′ and a portion of the upper surface 10u of the blocking layer 10.

As illustrated in FIG. 5I, the blocking layer 10 is removed by using, for example, the thermal degradation, the plasma bombard, the electrical-assisted desorption, etc. The liner 228 includes the protrusion 2281 protruding relative to the lateral surface of the second barrier layer 127. The protrusion 2281 is separated from the upper surface 123u of the first liner 123 by the gap G1.

As illustrated in FIG. 5J, the metal conductive portion Mₓ₊₁ filling the metal-trench 126h and the gap G1 and over the second barrier layer material 127′ is formed by using, for example, CVD, ALD, PVD, ECP, electroless plating, etc.

Then, the metal conductive portion Mₓ₊₁, the barrier layer 1271′ and the liner 1281′ may be planarized by, for example, CMP, to from the semiconductor structure 200 in FIG. 2.

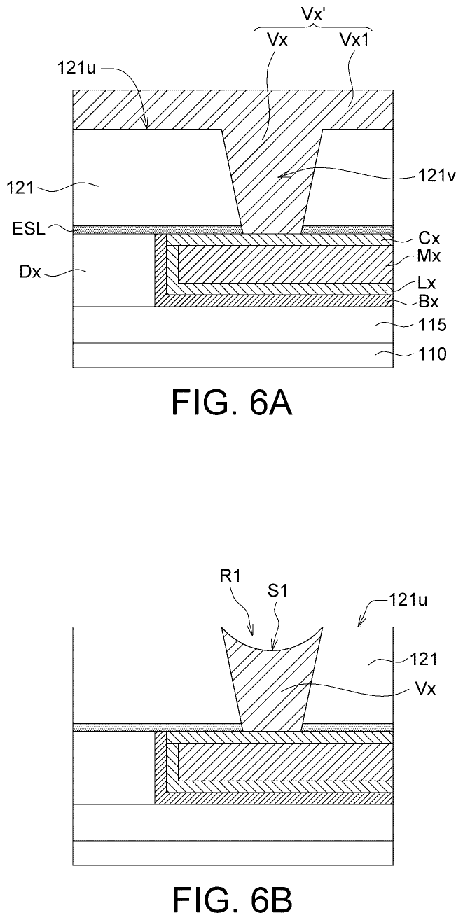

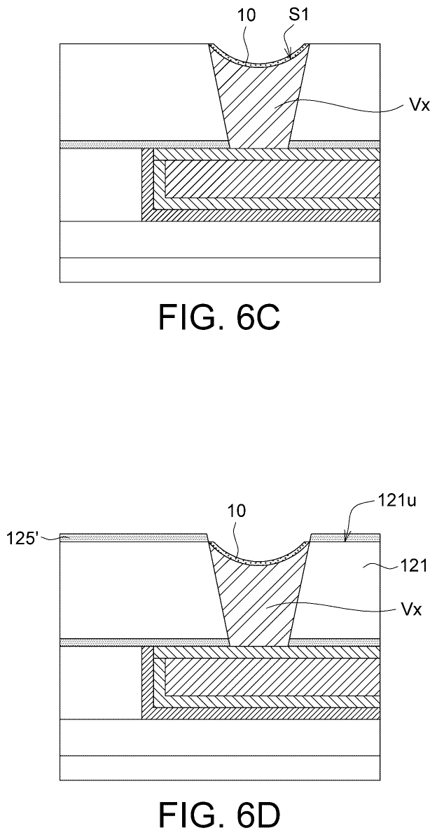

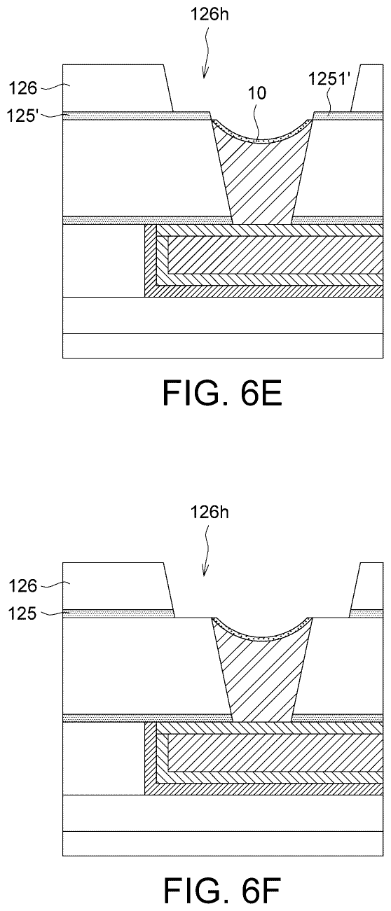

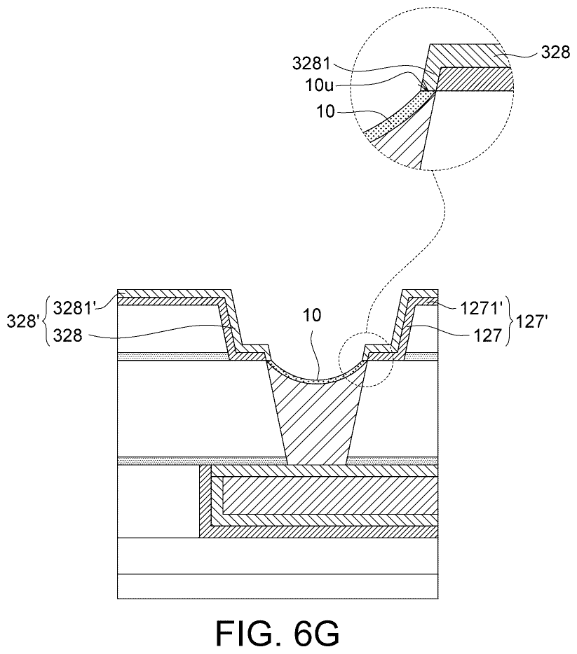

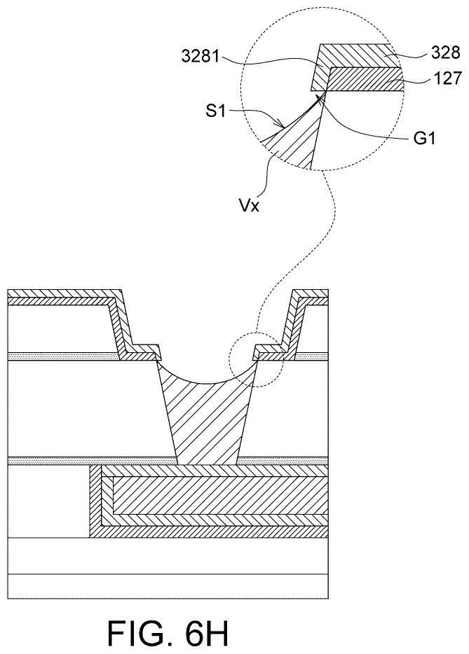

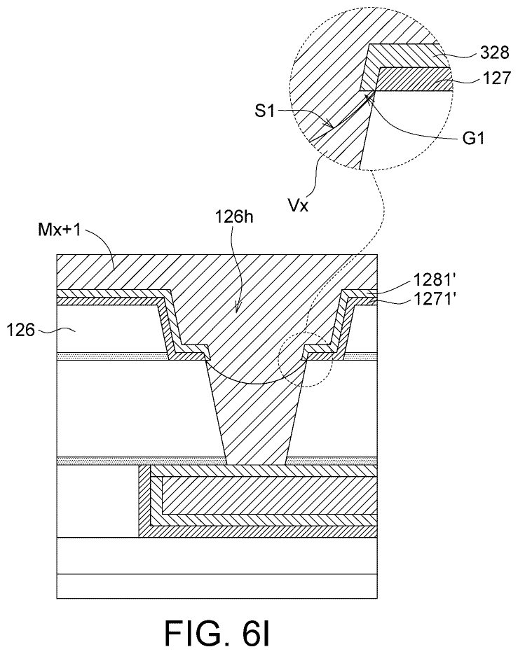

FIGS. 6A to 6I illustrate schematic diagrams of manufacturing processes of the semiconductor structure 300 in FIG. 3.

As illustrated in FIG. 6A, the MEOL layer 115 is formed on the substrate 110. The dielectric layer Dₓ having at least one hole within which the barrier layer Bₓ, the liner Lₓ, the metal conductive portion Mₓ and the cap Cₓ are formed. The etching stop layer ESL is formed on the dielectric layer Dₓ, and the cap Cₓ. The first dielectric layer 121 is formed on the etching stop layer ESL. The via-hole 121v is formed in the first dielectric layer 121 by using, for example, lithography, etc., and the via-hole 121v may stop at a portion of the etching stop layer ESL exposed from the via-hole 121v. Then, the portion of the etching stop layer ESL which is exposed from the via-hole 121v is removed by using, for example, wet etching. Then, the via conductive portion material Vₓ′ including the via conductive portion Vₓ and the conductive portion Vₓ₁ by using, for example, deposition, etc. The via conductive portion Vₓ is formed within the via-hole 121v, and the conductive portion Vₓ₁ is formed on the upper surface 121u of the first dielectric layer 121.

As illustrated in FIG. 6B, the via conductive portion Vₓ and the first dielectric layer 121 may be planarized by using, for example, CMP. After planarized, the via conductive portion Vₓ forms the upper surface S1, and the first dielectric layer 121 forms the upper surface 121u. The upper surface S1 may be recessed relative to the upper surface 121u to form the recess R1.

As illustrated in FIG. 6C, the blocking layer 10 over the upper surface S1 of the via conductive portion Vₓ is formed by using, for example, a dry process (for example, CVD, ALD, etc.) or a wet process (for example, spin coating, immersion, etc.). The material for the blocking layer 10 may be small molecules (for example, N-containing organic compound) or macromolecules (for example, polymer with functional group). The blocking layer material may be adsorbed on the specific material (for example, the via conductive portion Vₓ) to form the blocking layer 10. The blocking layer 10 may have a thickness ranging can be 1 Å to 1 μm.

As illustrated in FIG. 6D, the first etching stop layer material 125′ over the upper surface 121u of the first dielectric layer 121 is formed by using, for example, deposition. Due to blocking of the blocking layer 10, the first etching stop layer material 125′ is not formed over the blocking layer 10. In addition, the first etching stop layer material 125′ may be formed of a material including an organic (for example, SiOC) and/or inorganic (for example, AlxNy, AlOx) material.

As illustrated in FIG. 6E, the second dielectric layer 126 having at least one metal-trench 126h is formed over the first etching stop layer material 125′ by, for example, lithography, etc. The metal-trench 126h stops at the blocking layer 10 and the portion 1251′ of the first etching stop layer material 125′ in, for example, etching process.

As illustrated in FIG. 6F, the portion 1251′ of the first etching stop layer material 125′ may be removed by using, for example, wet etching.

As illustrated in FIG. 6G, a second barrier layer material 127′ including the second barrier layer 127 and the barrier layer 1271′ is formed by using, for example, ALD, CVD, wet coating process, etc. The second barrier layer 127 is formed on sidewalls of the metal-trench 126h, and the barrier layer 1271′ is formed on the upper surface 126u of the second dielectric layer 126. Then, a second liner material 328′ including the second liner 328 and the liner 1281′ is formed by, for example, ALD, CVD and wet coating process. The second liner 328 is formed over the second barrier layer 127, and the liner 1281′ is formed over the barrier layer 1271′ and a portion of the upper surface 10u of the blocking layer 10.

As illustrated in FIG. 6H, the blocking layer 10 is removed by using, for example, the thermal degradation, the plasma bombard, the electrical-assisted desorption, etc. The liner 328 includes the protrusion 3281 protruding relative to the lateral surface of the second barrier layer 127. The protrusion 3281 is separated from the upper surface S1 of the via conductive portion Vₓ by the gap G1.

As illustrated in FIG. 6I, the metal conductive portion Mₓ₊₁ filling the metal-trench 126h and the gap G1 and over the second barrier layer material 127′ is formed by using, for example, CVD, ALD, PVD, ECP, electroless plating, etc.

Then, the metal conductive portion Mₓ₊₁, the barrier layer 1271′ and the liner 1281′ may be planarized by, for example, CMP, to from the semiconductor structure 300 in FIG. 3.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a substrate and a BEOL layer disposed on the substrate. The BEOL layer includes a first dielectric layer, a via conductive portion, a second dielectric layer and a liner. The first dielectric layer has a surface and a via-hole extends from the surface. The via conductive portion is disposed within the via-hole and ha s a recess recessed relative to the surface. The second dielectric layer is disposed on the first dielectric layer, wherein the second dielectric layer has a metal-trench exposing the recess. The liner is disposed on a sidewall of the metal-trench and separated from the via conductive portion. In the present embodiment, there is no residue ESL material in the recess, and thus the resistance of the conductive portion may be effectively reduced.

Example embodiment 1: a semiconductor structure includes a substrate and a back end of line (BEOL) layer disposed on the substrate. The BEOL layer includes a first dielectric layer, a via conductive portion, a second dielectric layer and a liner. The first dielectric layer has a surface and a via-hole extends from the surface. The via conductive portion is disposed within the via-hole and ha s a recess recessed relative to the surface. The second dielectric layer is disposed on the first dielectric layer, wherein the second dielectric layer has a metal-trench exposing the recess. The liner is disposed on a sidewall of the metal-trench and separated from the via conductive portion.

Example embodiment 2 based on Example embodiment 1: the BEOL layer further includes a metal conductive portion. The metal conductive portion is disposed within the metal-trench and extends to the via conductive portion.

Example embodiment 3 based on Example embodiment 2: the metal conductive portion is contact with the via conductive portion.

Example embodiment 4 based on Example embodiment 1: the BEOL layer further includes a first liner within the via-hole, the liner is a second liner spaced from the via conductive portion by a gap, and the BEOL layer further includes a metal conductive portion within the gap.

Example embodiment 5 based on Example embodiment 1: the BEOL layer further includes a cap covering the via conductive portion. The cap and the liner are formed of the same material.

Example embodiment 6 based on Example embodiment 5: the cap is separated from the liner.

Example embodiment 7 based on Example embodiment 5: the BEOL layer further includes a metal conductive portion in contact with the cap.

Example embodiment 8 based on Example embodiment 1: there is no any etching stop layer within the via-hole.

Example embodiment 9 based on Example embodiment 8: a semiconductor structure includes a substrate and a BEOL layer disposed on the substrate. The BEOL layer includes a first dielectric layer, a via conductive portion, a second dielectric layer and a metal conductive portion. The first dielectric layer has a surface and a via-hole extending from the surface. The via conductive portion is disposed within the via-hole and has a recess recessed relative to the surface, wherein the via conductive portion is contact with a sidewall of the via-hole. The second dielectric layer is disposed on the first dielectric layer. The metal conductive portion is contact with the via conductive portion.

Example embodiment 10 based on Example embodiment 9: the second dielectric layer has a metal-trench exposing the recess, and the BEOL layer further includes a liner on a sidewall of the metal-trench and is separated from the via conductive portion by a gap. The metal conductive portion fills the gap.

Example embodiment 11: a manufacturing method for a semiconductor structure includes the following steps: providing a substrate; and forming a BEOL layer on the substrate, includes: forming a first dielectric layer, wherein the first dielectric layer has a surface and a via-hole extending from the surface; forming a via conductive portion disposed within the via-hole, wherein the via conductive portion has a recess recessed relative to the surface; forming a second dielectric layer, wherein the second dielectric layer has a metal-trench exposing the via conductive portion; and forming a liner on a sidewall of the metal-trench, wherein the liner is separated from the via conductive portion.

Example embodiment 12 based on Example embodiment 11: the manufacturing method further includes: forming an etching stop layer on the first dielectric layer. Before forming the etching stop layer on the first dielectric layer, the manufacturing method further includes: forming a blocking layer over the via conductive portion.

Example embodiment 13 based on Example embodiment 12: after forming the etching stop layer on the first dielectric layer, the manufacturing method further includes: removing the blocking layer.

Example embodiment 14 based on Example embodiment 12: in forming the blocking layer over the via conductive portion, the etching stop layer does not cover the blocking layer.

Example embodiment 15 based on Example embodiment 12: in forming the liner on the sidewall of the metal-trench, the liner extends to the blocking layer.

Example embodiment 16 based on Example embodiment 11: in forming the BEOL layer on the substrate further include: forming a metal conductive portion within the metal-trench, wherein the metal conductive portion extends to the via conductive portion.

Example embodiment 17 based on Example embodiment 16: the metal conductive portion is contact with the via conductive portion.

Example embodiment 18 based on Example embodiment 11: in forming the liner on the sidewall of the metal-trench, the liner is spaced from the via conductive portion by a gap; the manufacturing method further includes: forming a metal conductive portion within the gap.

Example embodiment 19 based on Example embodiment 11: the manufacturing method further includes: forming a cap, wherein the cap covers the via conductive portion. The cap and the liner are formed of the same material.

Example embodiment 20 based on Example embodiment 19: in forming the liner on the sidewall of the metal-trench, the liner is spaced from the cap by a gap; the manufacturing method further includes: forming a metal conductive portion within the gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate; and
a back end of line (BEOL) layer disposed on the substrate, and comprising:
a first dielectric layer having a surface and a via-hole extending from the surface;
a via conductive portion disposed within the via-hole and having a recess recessed relative to the surface;
a second dielectric layer on the first dielectric layer, wherein the second dielectric layer has a metal-trench exposing the recess; and
a liner on a sidewall of the metal-trench and separated from the via conductive portion.

2. The semiconductor structure as claimed in claim 1, wherein the BEOL layer further comprises:
a metal conductive portion within the metal-trench and extending to the via conductive portion.

3. The semiconductor structure as claimed in claim 2, wherein the metal conductive portion is contact with the via conductive portion.

4. The semiconductor structure as claimed in claim 1, wherein the BEOL layer further comprises a first liner within the via-hole, the liner is a second liner spaced from the via conductive portion by a gap, and the BEOL layer further comprises:
a metal conductive portion within the gap.

5. The semiconductor structure as claimed in claim 1, wherein the BEOL layer further comprises:
a cap covering the via conductive portion;
wherein the cap and the liner are formed of the same material.

6. The semiconductor structure as claimed in claim 5, wherein the cap is separated from the liner.

7. The semiconductor structure as claimed in claim 5, wherein the BEOL layer further comprises:
a metal conductive portion in contact with the cap.

8. The semiconductor structure as claimed in claim 1, wherein there is no any etching stop layer within the via-hole.

9. A semiconductor structure, comprising:
a substrate; and
a BEOL layer disposed on the substrate, and comprising:
a first dielectric layer having a surface and a via-hole extending from the surface;
a via conductive portion disposed within the via-hole and having a recess recessed relative to the surface, wherein the via conductive portion is contact with a sidewall of the via-hole;
a second dielectric layer on the first dielectric layer; and
a metal conductive portion being contact with the via conductive portion.

10. The semiconductor structure as claimed in claim 9, wherein the second dielectric layer has a metal-trench exposing the recess, and the BEOL layer further comprises:
a liner on a sidewall of the metal-trench and separated from the via conductive portion by a gap;
wherein the metal conductive portion fills the gap.

11. A manufacturing method for a semiconductor structure, comprising:
providing a substrate; and
forming a BEOL layer on the substrate, comprising:
forming a first dielectric layer, wherein the first dielectric layer has a surface and a via-hole extending from the surface;
forming a via conductive portion disposed within the via-hole, wherein the via conductive portion has a recess recessed relative to the surface;
forming a second dielectric layer, wherein the second dielectric layer has a metal-trench exposing the via conductive portion; and
forming a liner on a sidewall of the metal-trench, wherein the liner is separated from the via conductive portion.

12. The manufacturing method as claimed in claim 11, further comprising:
forming an etching stop layer on the first dielectric layer;
wherein before forming the etching stop layer on the first dielectric layer, the manufacturing method further comprises:
forming a blocking layer over the via conductive portion.

13. The manufacturing method as claimed in claim 12, wherein after forming the etching stop layer on the first dielectric layer, the manufacturing method further comprising:
removing the blocking layer.

14. The manufacturing method as claimed in claim 12, wherein in forming the blocking layer over the via conductive portion, the etching stop layer does not cover the blocking layer.

15. The manufacturing method as claimed in claim 12, wherein in forming the liner on the sidewall of the metal-trench, the liner extends to the blocking layer.

16. The manufacturing method as claimed in claim 11, wherein forming the BEOL layer on the substrate further comprises:
forming a metal conductive portion within the metal-trench, wherein the metal conductive portion extends to the via conductive portion.

17. The manufacturing method as claimed in claim 16, wherein the metal conductive portion is contact with the via conductive portion.

18. The manufacturing method as claimed in claim 11, wherein in forming the liner on the sidewall of the metal-trench, the liner is spaced from the via conductive portion by a gap; the manufacturing method further comprises:
forming a metal conductive portion within the gap.

19. The manufacturing method as claimed in claim 11, further comprising:
forming a cap, wherein the cap covers the via conductive portion;
wherein the cap and the liner are formed of the same material.

20. The manufacturing method as claimed in claim 19, wherein in forming the liner on the sidewall of the metal-trench, the liner is spaced from the cap by a gap; the manufacturing method further comprises:
forming a metal conductive portion within the gap.
